(19) United States
(12) Patent Application Publication
(10) Pub. No.: US 2024/0389406 A1
(43) Pub. Date: Nov. 21, 2024

(54) DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Shaopeng LI, Beijing (CN); Yuan LIU, Beijing (CN); Weiben ZHANG, Beijing (CN); Peng WANG, Beijing (CN); Rongkun FAN, Beijing (CN); Jialin WANG, Beijing (CN); Bilun ZHANG, Beijing (CN); Dingjie HUANG, Beijing (CN); Fei LI, Beijing (CN); Leihan WANG, Beijing (CN); Cheng ZHANG, Beijing (CN)

(21) Appl. No.: 18/695,843

(22) PCT Filed: Jun. 12, 2023
(86) PCT No.: PCT/CN2023/099602

§ 371 Date: Mar. 27, 2024

(30) Foreign Application Priority Data
Jun. 21, 2022 (CN) 202210708994.7

(51) Int. Cl. H10K 59/127

(52) U.S. Cl. CPC H10K 59/1275

(57) ABSTRACT

Provided is a display device. The display device includes a display substrate and a drive assembly; wherein the display substrate has a first bonding region, and the drive assembly has a second bonding region corresponding to the first bonding region; and the display substrate includes a first limiting assembly disposed outside the first bonding region, and the drive assembly includes a second limiting assembly disposed outside the second bonding region and engaged with the first limiting assembly; wherein the first limiting assembly is configured to engage with the second limiting assembly to restrict relative movement between the drive assembly and the display substrate during bonding the first bonding region to the second bonding region.

### CROSS-REFERENCE TO RELATED APPLICATION

This application is a U.S. national phase application based on PCT/CN2023/099602, filed on Jun. 12, 2023, which claims priority to Chinese patent Application No. 202210728994.7, filed on Jun. 21, 2022 and entitled “DISPLAY PANEL AND DISPLAY DEVICE”, the contents of which are incorporated herein by reference in their entireties.

### TECHNICAL FIELD

The present disclosure related the field of display technology, and in particular to a display device.

### BACKGROUND

Organic Light-Emitting Diode (OLED) display panels are favored by more and more consumers due to their advantages of self-illumination, fast response, wide viewing angle, flexibility, and slimness. With the development of OLED, higher resolution of products is demanded in the OLED market.

### SUMMARY

The present disclosure provides a display device. The technical solutions are as follows.

A display device is provided. The display device includes: a display substrate and a drive assembly;
wherein the display substrate has a first bonding region, and the drive assembly has a second bonding region corresponding to the first bonding region; and
the display substrate includes a first limiting assembly disposed outside the first bonding region, and the drive assembly includes a second limiting assembly disposed outside the second bonding region and engaged with the first limiting assembly;
wherein the first limiting assembly is configured to engage with the second limiting assembly to restrict relative movement between the drive assembly and the display substrate during bonding the first bonding region to the second bonding region.

In some embodiments, the display substrate includes a plurality of first limiting assemblies, and the drive assembly includes a plurality of second limiting assemblies, the plurality of first limiting assemblies being in one-to-one correspondence to the plurality of second limiting assemblies;
wherein each of the first limiting assemblies includes at least one first limiting portion, each of the second limiting assemblies includes at least one second limiting portion, wherein the first limiting portion of the first limiting assembly is configured to be abutted against the second limiting portion of the second limiting assembly corresponding to the first limiting assembly.

In some embodiments, in the case that each of the first limiting assemblies includes the first limiting portion and each of the second limiting assemblies includes the second limiting portion, each of the first limiting assemblies is disposed on a side, closer to the first bonding region, relative to the second limiting assembly corresponding to the first limiting assembly, or each of the second limiting assemblies is disposed on a side, closer to the first bonding region, relative to the first limiting assembly corresponding to the second assembly.

In some embodiments, a limiting groove is disposed in one of the first limiting assembly and the second limiting assembly, and the other of the first limiting assembly and the second limiting assembly is disposed in the limiting groove.

In some embodiments, the first limiting assembly includes at least two first limiting portions, two adjacent first limiting portions are configured to define the limiting groove, and the second limiting portion of the second limiting assembly is disposed in the limiting groove.

In some embodiments, the limiting groove includes a first sub-groove and a second sub-groove in communication with the first sub-groove, an extension direction of the first sub-groove is intersected with an extension direction of the second sub-groove, and the second limiting portion includes a first sub-limiting plate disposed in the first sub-groove and a second sub-limiting plate disposed in the second sub-groove.

In some embodiments, one side of the first sub-limiting plate is fixedly connected to one side of the second sub-limiting plate.

In some embodiments, a first chamber is formed at an edge of a side, away from the side of the second sub-limiting plate, of the first sub-limiting plate, and/or, a second chamber is formed at an edge, away from the first sub-limiting plate, of the second sub-limiting plate.

In some embodiments, an angle between the first sub-limiting plate and the second sub-limiting plate ranges from 600 to 120°.

In some embodiments, a shape of at least one of the first sub-limiting portions disposed on both sides of the second sub-limiting portion has is same as a shape of the second sub-limiting portion.

In some embodiments, a shape of the limiting groove includes any one of: a circle, an arc, a square, a parallelogram, a triangle, a rhombus, a cross and a Y-shape.

In some embodiments, the display substrate further includes a first substrate, the first limiting portion being fixed to the first substrate, and the drive assembly further includes a second substrate, the second limiting portion being fixed to the second substrate;
wherein a first guide structure is disposed on a side, away from the first substrate, of the first substrate, and/or, a second guide structure is disposed on a side, away from the second substrate, of the second substrate.

In some embodiments, the first guide structure includes a third chamfer, the third chamfer being disposed on a side, close to the limiting groove, of the first limiting portion; and/or, the second guide structure includes a fourth chamfer, the fourth chamfer being disposed on a side, close to the first limiting portion, of the second limiting portion.

In some embodiments, a shape of the first bonding region is a square shape, and the plurality of first limiting assemblies are disposed at least at diagonal positions of the first bonding region.

In some embodiments, the plurality of the first limiting assemblies include a first primary limiting assembly arranged towards corners of the first bonding region, and at least one first auxiliary limiting assembly arranged between two adjacent corners of the first bonding region.

In some embodiments, the display substrate further includes a plurality of first bonding electrodes disposed in the first bonding region, and the drive assembly further includes a plurality of second bonding electrodes disposed in the second bonding region;
wherein the plurality of first bonding electrodes are one-to-one electrically connected to the plurality of second bonding electrodes in the case that the first bonding region is bonded to the second bonding region, in a thickness direction of the display substrate, a height of the first limiting assembly is greater than or equal to a height of the first bonding electrodes, and a height of the second limiting assembly is greater than or equal to a height of the second bonding electrodes.

In some embodiments, the first limiting assembly and the first bonding electrode are disposed in one layer have a same material, and/or, the second limiting assembly and the second bonding electrode are disposed in one layer and have a same material.

In some embodiments, the first bonding electrode is configured to be electrically connected to a conductive structure within the display substrate, and the second bonding electrode is configured to be electrically connected to a conductive structure within the drive assembly;
wherein the conductive structure within the display substrate is insulated from the first limiting assembly, and/or the conductive structure within the drive assembly is insulated from the second bonding assembly.

In some embodiments, the display substrate further includes a plurality of light-emitting elements, the first bonding electrode is electrically connected to the light-emitting elements, the drive assembly further includes an integrated circuit, and the second bonding electrode is electrically connected to the integrated circuit.

In some embodiments, the display device further includes a conductive adhesive disposed between the display substrate and the drive assembly, and the first bonding region is bound to the second bonding region via the conductive adhesive.

### BRIEF DESCRIPTION OF DRAWINGS

In order to describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art can still derive other drawings from these accompanying drawings without creative efforts.

FIG. 1 is a cross-section diagram of a display substrate and a drive assembly prior to bonding in a display device in the related art;

FIG. 2 is a cross-section diagram of a display substrate and a drive assembly upon bonding in a display device in the related art;

FIG. 3 is a schematic structural diagram of a display device according to some embodiments of the present disclosure;

FIG. 4 is a schematic structural diagram of a display substrate according to some embodiments of the present disclosure;

FIG. 5 is a schematic structural diagram of a drive assembly according to some embodiments of the present disclosure;

FIG. 6 is a cross-section diagram of a display substrate and a drive assembly upon bonding in a display device according to some embodiments of the present disclosure;

FIG. 7 is a schematic structural diagram of another display substrate according to some embodiments of the present disclosure;

FIG. 8 is a schematic structural diagram of another drive assembly according to some embodiments of the present disclosure;

FIG. 9 is a schematic diagram of a first limiting assembly engaged with a second limiting assembly according to some embodiments of the present disclosure;

FIG. 10 is a schematic diagram of another first limiting assembly engaged with a second limiting assembly according to some embodiments of the present disclosure;

FIG. 11 is a top view of a first limiting assembly according to some embodiments of the present disclosure;

FIG. 12 is a top view of a second limiting assembly according to some embodiments of the present disclosure;

FIG. 13 is a top view of another second limiting assembly according to some embodiments of the present disclosure;

FIG. 14 is a top view of another first limiting assembly according to some embodiments of the present disclosure;

FIG. 15 is a top view of still another first limiting assembly according to some embodiments of the present disclosure;

FIG. 16 is a three-dimensional view of the first limiting assembly illustrated in FIG. 15;

FIG. 17 is a top view of still another first limiting assembly according to some embodiments of the present disclosure;

FIG. 18 is a possible top view of a first limiting assembly in a different scenario according to some embodiments of the present disclosure;

FIG. 19 is a partially enlarged view of a display device according to some embodiments of the present disclosure;

FIG. 20 is a cross-section diagram of a first limiting assembly prior to being engaged with a second limiting assembly according to some embodiments of the present disclosure;

FIG. 21 is a partial top view of a display substrate at a first bonding region according to some embodiments of the present disclosure;

FIG. 22 is a partial top view of another display substrate at a first bonding region according to some embodiments of the present disclosure;

FIG. 23 is a partial top view of still another display substrate at a first bonding region according to some embodiments of the present disclosure;

FIG. 24 is a cross-section diagram of a display substrate and a drive assembly prior to bonding in a display device according to some embodiments of the present disclosure; and

FIG. 25 is a cross-section diagram of a display substrate and a drive assembly upon bonding in another display device according to some embodiments of the present disclosure.

### DETAILED DESCRIPTION

In order to make the objects, technical solutions and advantages of the present disclosure clearer, embodiments of the present disclosure are described in further detail below in conjunction with the accompanying drawings.

It should be noted that, unless additional defined, technical terms or scientific terms in the embodiments of the present disclosure shall have the ordinary meaning understood by those skilled in the art to which the present disclosure belongs. The terms “first”, “second”, and the like in the present embodiments do not indicate any order, number, or importance, but are only used to distinguish different components. The words “including” or “comprising” and similar words indicate that the component, object or method step preceding the word contains the component, object or method step upon the word and its equivalents, without excluding other components, objects or method steps. Words such as “connected” or “coupled” are not limited to physical or mechanical connections, but includes electrical connections, whether direct or indirect. The words “up”, “down”, “left”, “right”, etc. are used only to indicate relative positional relationships. When the absolute position of the described object is changed, the relative positional relationship may be changed accordingly.

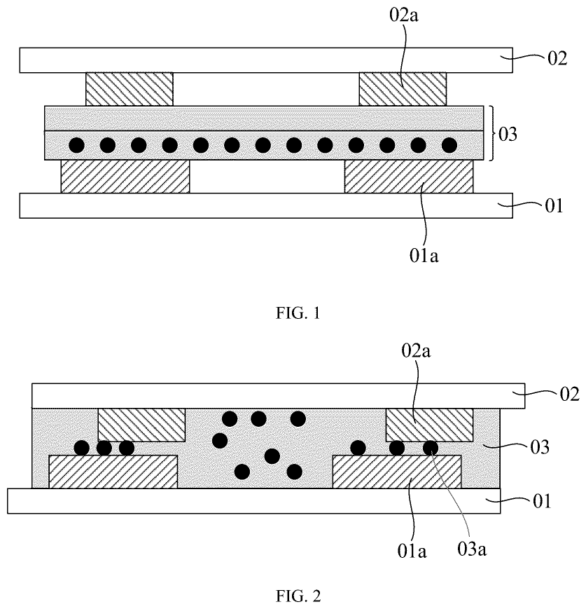

Referring to FIG. 1, FIG. 1 is a cross-section diagram of a display substrate and a drive assembly prior to bonding in a display device in the related art. The display substrate 01 in the display device has a plurality of first bonding electrodes Ola, and the drive assembly 02 in the display device has a plurality of second bonding electrodes 02a. The plurality of second bonding electrodes 02a in the drive assembly 02 are one-to-one electrically connected to the plurality of first bonding electrodes Ola in the display substrate 01. In this way, the drive assembly 02 outputs an electrical signal to the display substrate 01 through the electrically connected second bonding electrodes 02a and the bonding electrodes Ola to control the light-emitting elements in the display panel 01 to emit light, such that the display substrate 01 displays the corresponding image.

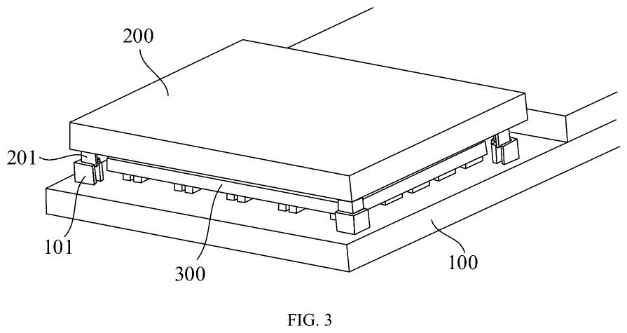

The display device further includes an anisotropic conductive film (ACF) disposed between the display substrate 01 and the drive assembly 02. Referring to FIG. 2, FIG. 2 is a cross-section diagram of a display substrate and a drive assembly upon bonding in a display device according to the related art. The drive assembly 02 is bonded to the display substrate 01 via the ACF conductive adhesive 03. Upon bonding, each second bonding electrode 02a in the drive assembly 02 is electrically connected to a corresponding first bonding electrode Ola in the display substrate 01 via the ACF conductive adhesive 03.

In the process of bonding the drive assembly 02 to the display substrate 01 via the ACF conductive adhesive 03, a pressing force needs to be applied to the drive assembly 02 to cause the adhesive of the ACF conductive adhesive 03 disposed between the second bonding electrodes 02a and the first bonding electrodes 01a to be extruded, such that the second bonding electrodes 02a are electrically connected to the first bonding electrodes Ola by the conductive particles 03a in the ACF conductive adhesive 03.

However, during the process of applying the pressing force to the drive assembly 02, the adhesive in the ACF conductive adhesive 03 is in a flowing state, and the adhesive in the flowing state drives the drive assembly 02 to move relative to the display substrate 01, resulting in misalignment between the second bonding electrode 02a in the drive assembly 02 and the corresponding first bonding electrode Ola in the display substrate 01, and a resulting in poor electrical connection between the second bonding electrode 02a and the corresponding first bonding electrode Ola. In this way, an undesirable phenomenon of bonding misalignment between the drive assembly 02 and the display substrate 01 occurs, which seriously affects the display effect of the display substrate 01.

In addition, with the technical development in the art, the resolution of the display device is higher and higher, and the quantity of bonding electrodes in the display device is greater and greater, resulting in the size of the bonding electrodes getting smaller and smaller. In this way, in the case that an undesirable phenomenon of bonding misalignment between the drive assembly 02 and the display substrate 01 is present, and the misalignment between the second bonding electrode 02a in the drive assembly 02 and the corresponding first bonding electrode Ola in the display substrate 01 is large, the situation that the second bonding electrode 02a cannot be electrically connected to the corresponding first bonding electrode Ola occurs, and the display substrate 01 cannot display normally.

Referring to FIG. 3, FIG. 3 is a schematic diagram of a structure of a display device according to some embodiments of the present disclosure. The display device includes a display substrate 100 and a drive assembly 200.

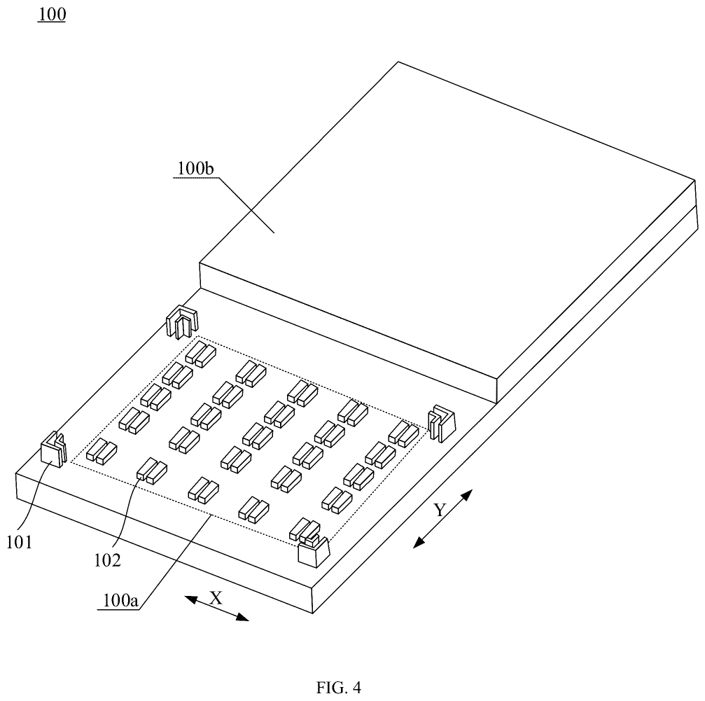

In order to see the structure of the display substrate 100 more clearly, please refer to FIG. 4. FIG. 4 is a schematic structural diagram of the display substrate according to some embodiments of the present disclosure. The display substrate 100 has a first bonding region 100a, and the display substrate 100 includes a first limiting assembly 101 disposed outside the first bonding region 100a. The display substrate 100 further typically includes a plurality of first bonding electrodes 102 disposed within the first bonding region 100a, and a plurality of light-emitting elements disposed within a display region 100b of the display substrate 100 (not shown in the figures). Exemplarily, the plurality of first bonding electrodes 102 disposed within the first bonding region 100a are arranged in a plurality of columns along the first direction X and in a plurality of rows along the second direction Y.

It should be noted that the first bonding region 100a of the display substrate 100 is a portion of a non-display region disposed outside of the display region 100b of the display substrate 100. The first bonding electrode 102 within the first bonding region 100a is electrically connected to the light-emitting element within the display region 100b. Exemplarily, a conductive structure configured to connect the first bonding electrode 102 with the light-emitting element is also typically disposed within the display substrate 100. For example, the conductive structure includes fan-out leads within the non-display region and drive signal lines within the display region 100b. The drive signal line is electrically connected to the light-emitting element, and one end of the fan-out lead is electrically connected to the drive signal line and the other end of the fan-out lead is electrically connected to the first bonding electrode 102. In this way, the first bonding electrode 102 is electrically connected to the light-emitting element via the fan-out lead and the drive signal line.

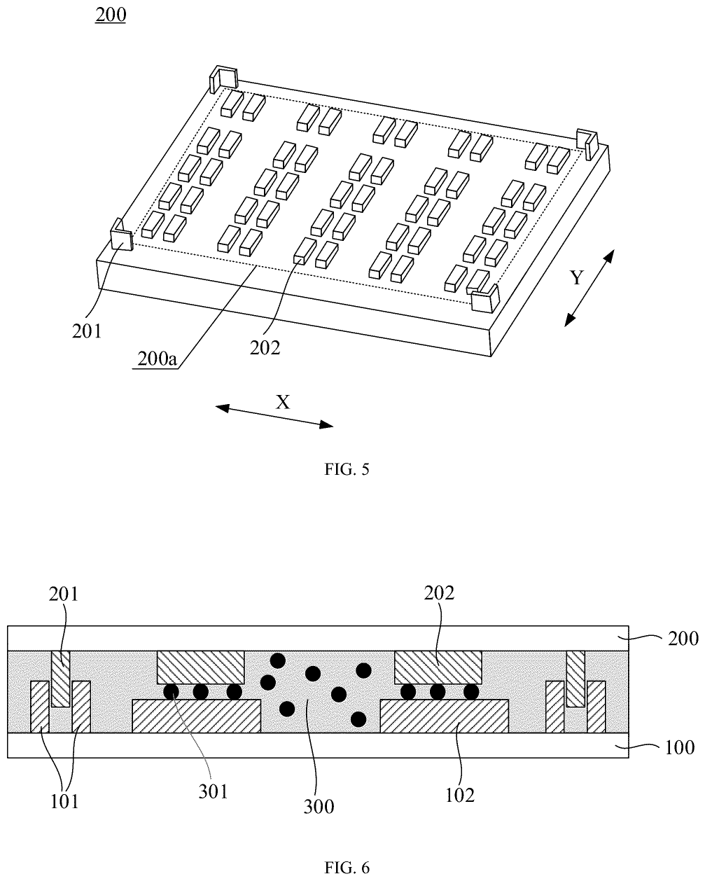

In order to see the structure of the drive assembly 200 more clearly, please refer to FIG. 5. FIG. 5 is a schematic structural diagram of a drive assembly according to some embodiments of the present disclosure. The drive assembly 200 has a second bonding region 200a corresponding to the first bonding region 100a, and the drive assembly 200 includes a second limiting assembly 201 disposed outside the second bonding region 200a and engaged with the first limiting assembly 101. The drive assembly 200 further typically includes a plurality of second bonding electrodes 202 disposed within the second bonding region 200a, and a second bonding electrode 202 electrically connected to the plurality of second bonding electrodes 202, and an integrated circuit (not shown in the figures) electrically connected to the plurality of second bonding electrodes 202. Exemplarily, the plurality of second bonding electrodes 202 disposed within the second bonding region 200a are arranged in a plurality of columns along the first direction X and in a plurality of rows along the second direction Y.

It should be noted that the drive assembly 200 is a drive chip or a flexible circuit board. In the case that the drive assembly 200 is a flexible circuit board, a chip provided with an integrated circuit needs to be encapsulated within the flexible circuit board. The integrated circuit in the drive assembly 200 can send a drive signal to the first bonding electrode 101 via the second bonding electrode 202, such that the first bonding electrode 101 can send this drive signal to the light-emitting element within the display substrate 100, which in turn enables the light-emitting element to be illuminated. In this way, the light-emitting state and light-emitting brightness of the light-emitting element within the display substrate 100 can be controlled by the drive assembly 200, such that the display substrate 100 can present a corresponding display screen.

In the present disclosure, the plurality of second bonding electrodes 202 in the drive assembly 200 are in one-to-one correspondence to the plurality of first bonding electrodes 102 in the display substrate 100. The display device 000 further includes a conductive adhesive 300 disposed between the display substrate 100 and the drive assembly 200. For example, the conductive adhesive 300 is an ACF conductive adhesive. The first bonding region 100a in the display substrate 100 is connected to the second bonding region 200a in the drive assembly 200 via the conductive adhesive 300. In the case that the first bonding region 100a is connected to the second bonding region 200a, each of the first bonding electrodes 102 within the first bonding region 100a is electrically connected via the conductive adhesive 300 to the corresponding second bonding electrode 202 within the second bonding region 200a.

In some embodiments of the present disclosure, the first limiting assembly 101 in the display substrate 100 is configured to engage with the second limiting assembly 201 to restrict relative movement between the drive assembly 200 and the display substrate 100 during bonding the first bonding region 100a to the second bonding region 200a.

Exemplarily, as shown in FIG. 6, FIG. 6 is a cross-section diagram of a display substrate and a drive assembly upon bonding in a display device according to some embodiments of the present disclosure. During the process of bonding the first bonding region 100a in the display substrate 100 to the second bonding region 200a in the drive assembly 200 via the conductive adhesive 300, the adhesive in the conductive adhesive 300 is in a flowing state, and the adhesive in the conductive adhesive 300 disposed between the second bonding electrode 202 and the first bonding electrode 102 is extruded, such that the second bonding electrode 202 is electrically connected to the first bonding electrode 102 by the conductive particles 301 in the conductive adhesive 300. Through the second limiting assembly 201 in the drive assembly 200 engaged with the first limiting assembly 101 in the display substrate 100, the relative movement between the drive assembly 200 and the display substrate 100 is restricted, such that the adhesive in the flowing state do not drive the drive assembly 200 to move relative to the display substrate 100.

For example, in the process of bonding the first bonding region 100a in the display substrate 100 to the second bonding region 200a in the drive assembly 200 via the conductive adhesive 300, the second limiting assembly 201 engaged with the first limiting assembly 101 ensures that the adhesive in the flowing state does not drive the drive assembly 200 to move relative to the display substrate 200 in the first direction X and the second direction Y.

In this way, the probability of misalignment between the second bonding electrode 201 in the drive assembly 200 and the corresponding first bonding electrode 101 in the display substrate 100 is effectively reduced, such that the drive assembly 200 and the display substrate 100 are bound with higher precision, the effect of the electrical connection between the second bonding electrode 201 and the corresponding first bonding electrode 101 is effectively improved, and the display substrate 100 achieves a better display effect.

In summary, the display device according to the embodiments of the present disclosure includes a display substrate and a drive assembly. In the process of bonding the first bonding region in the display substrate to the second bonding region in the drive assembly by the conductive adhesive, the adhesive in the conductive adhesive is in a flowing state. By the engagement between the second limiting assembly in the drive assembly and the first limiting assembly in the display substrate, the relative movement between the drive assembly and the display substrate is restricted, such that the adhesive in the flowing state do not drive the drive assembly to move relative to the display substrate. In this way, the probability of misalignment between the second bonding electrode in the drive assembly and the corresponding first bonding electrode in the display substrate is effectively reduced, such that the drive assembly and the display substrate are bound with a higher precision, the effect of the electrical connection between the second bonding electrode and the corresponding first bonding electrode is improved, and the display substrate achieves a better display effect.

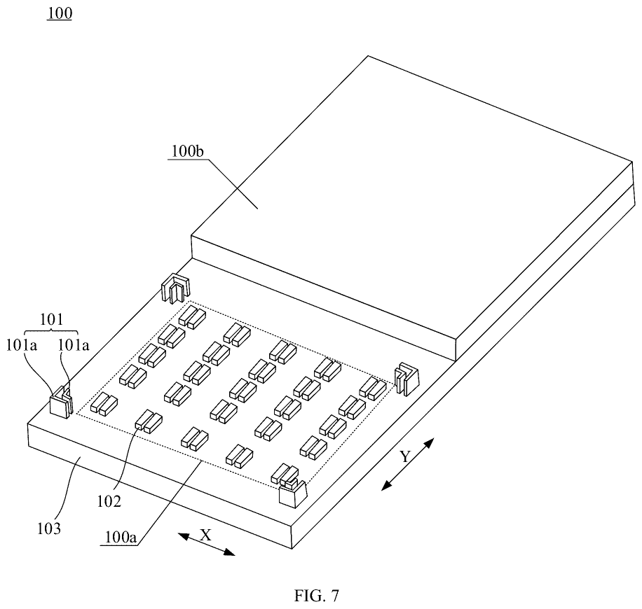

In some embodiments, as shown in FIG. 7, FIG. 7 is a schematic structural diagram of another display substrate according to some embodiments of the present disclosure. The display substrate 100 includes a plurality of first limiting assemblies 101, and each of the first limiting assemblies 101 includes at least one first limiting portion 101a. The display substrate 100 further includes a first substrate 103, and the plurality of first limiting assemblies 101 and the plurality of first bonding electrodes 102 in the display substrate 100 are fixed on the same side of the first substrate 103.

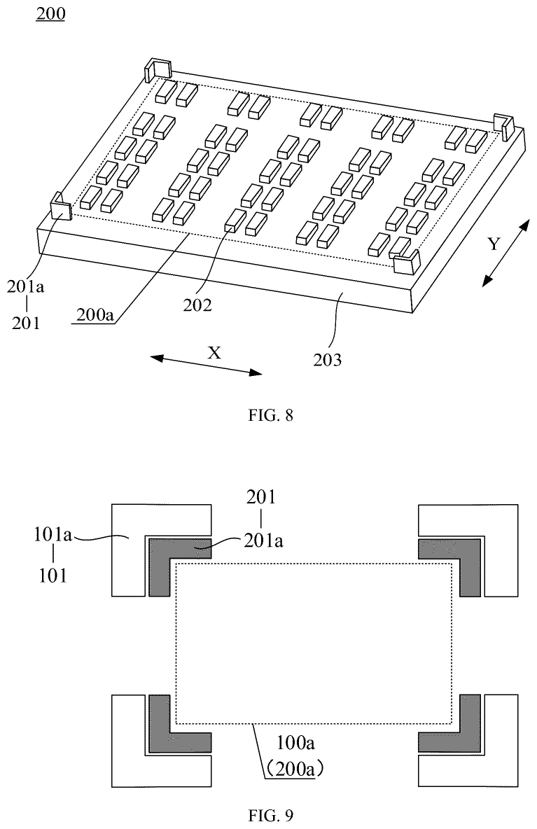

As shown in FIG. 8, FIG. 8 is a schematic structural diagram of another drive assembly according to some embodiments of the present disclosure. The drive assembly 200 includes a plurality of second limiting assemblies 201, and each of the second limiting assemblies 201 includes at least one second limiting portion 201a. The drive assembly 200 further includes a second substrate 203, and the plurality of second limiting assemblies 201 and the plurality of second bonding electrodes 202 in the drive assembly 200 are fixed on the same side of the second substrate 203.

The plurality of first limiting assemblies 101 in the display substrate 100 are in one-to-one correspondence to the plurality of second limiting assemblies 202 in the drive assembly 200, and a first limiting portion 1011 in each of the first limiting assemblies 101 is configured to be abutted against a second limiting portion 2011 in the corresponding second limiting assembly 201. In this way, in the process of bonding the display substrate 100 to the drive assembly 200, the engagement between the plurality of first limiting assemblies 101 and the plurality of second limiting assemblies 201 enables further limiting of the drive assembly 200, such that the conductive adhesive 300 in a flowing state do not drive the drive assembly 200 to move relative to the display substrate 100.

In the embodiments of the present disclosure, the forms of the first limiting assembly 101 in the display substrate 100 are various, and the forms of the second limiting assembly 201 in the corresponding drive assembly 200 are various. The embodiments of the present disclosure are illustrated by the following two possible implementations.

The first possible implementation is shown in FIG. 9. FIG. 9 is a schematic diagram of a first limiting assembly engaged with a second limiting assembly according to some embodiments of the present disclosure. Each of the first limiting assemblies 101 includes a first limiting portion 101a, and each of the second limiting assemblies 201 includes a second limiting portion 201a. That is, the quantity of the first limiting portions 101a in each of the first limiting assemblies 101 is one, the quantity of the second limiting portions 201a in each of the second limiting assemblies 201 is one. Neither the first limiting portion 101a nor the second limiting portion 201a is provided with a limiting groove. In this way, the first limiting assembly 101 is disposed closer to a side of the first bonding region 100a with respect to the corresponding second limiting assembly 201, or, the second limiting assembly 201 is disposed closer to a side of the first bonding region 100a with respect to the corresponding first limiting assembly 101. It should be noted that FIG. 9 is illustrated with the second limiting assembly 201 being disposed closer to the side of the first bonding region 100a relative to the corresponding first limiting assembly 101.

In the case that the first limiting assembly 101 is disposed on a side closer to the first bonding region 100a with respect to the corresponding second limiting assembly 201, the drive assembly 200 can be restricted from being displaced in the horizontal direction with respect to the display substrate 100 by the second limiting assembly 201 during the process of bonding the display substrate 100 to the drive assembly 200. Similarly, in the case that the second limiting assembly 201 is disposed closer to the side of the first bonding region 100a with respect to the corresponding first limiting assembly 101, the drive assembly 200 can be restricted from being displaced in the horizontal direction with respect to the display substrate 100 during the bonding of the display substrate 100 with the drive assembly 200 by the first limiting assembly 101.

In some embodiments, the first limiting portion 101a in the first limiting assembly 101 is an L-shaped limiting plate, and the second limiting portion 201a in the second limiting assembly 201 is also an L-shaped limiting plate. In this case, in the process of bonding the display substrate 100 to the drive assembly 200, it can be ensured that the drive assembly 200 does not move in the first direction X with respect to the display substrate 100, and it can be ensured that the drive assembly 200 does not move in the second direction Y with respect to the display substrate 100, by being abutted against the first limiting portion 101a and the second limiting portion 201a.

It is to be noted that in the first limiting portion 101a and the second limiting portion 201a, the size of the limiting portion closer to the first bonding region 100a is smaller, while the size of the limiting portion away from the first bonding region 100a is larger. For example, in the case that the second limiting assembly 201 is disposed closer to the side of the first bonding region 100a relative to the corresponding first limiting assembly 101, the size of the second limiting portion 201a in the second limiting assembly 201 is smaller than the size of the first limiting portion 101a in the first limiting assembly 101. In this way, a higher stability can be ensured when the first limiting portion 101a is abutted against the second limiting portion 201a.

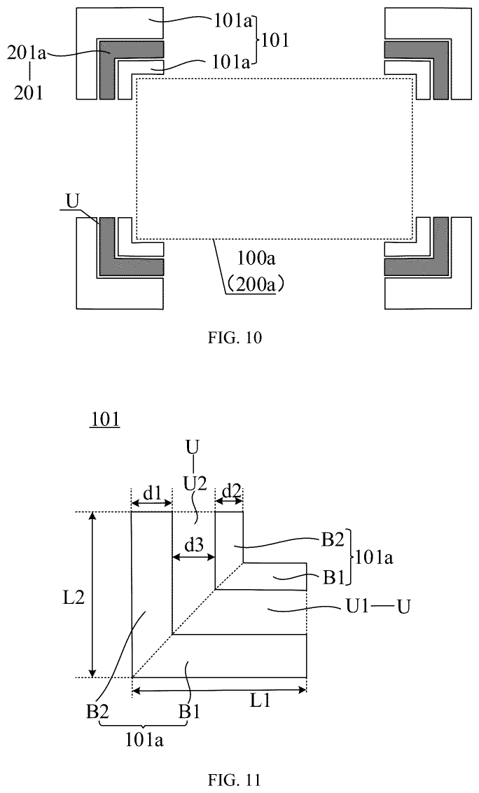

In the second optional implementation, as shown in FIG. 10, FIG. 10 is a schematic diagram of another first limiting assembly engaged with a second limiting assembly according to some embodiments of the present disclosure. A limiting groove U is disposed in one of the first limiting assembly 101 and the second limiting assembly 201, and the other of the first limiting assembly 101 and the second limiting assembly 201 is disposed in the limiting groove U. It should be noted that the first limiting assembly 101 is illustrated in FIG. 10 with the limiting groove U being disposed in the first limiting assembly 101 and a portion of the second limiting assembly 201 being disposed in the limiting groove U. In this way, each of the second limiting assemblies 201 in the drive assembly 200 can extend into the corresponding first limiting assembly 101 in the limiting groove U, such that the second limiting assembly 201 is able to be abutted against the first limiting assembly 101 in the limiting groove U. In this way, during the process of bonding the display substrate 100 to the drive assembly 200, the movement of the drive assembly 200 in the horizontal direction relative to the display substrate 100 is limited by the portion of the second limiting assembly 201 that extends into the limiting groove U of the corresponding first limiting assembly 101.

In embodiments of the present disclosure, as shown in FIG. 10, the first limiting assembly 101 includes at least two first limiting portions 101a, and between two adjacent first limiting portions 101a is configured to define a limiting groove U in the first limiting assembly 101. The second limiting portion 201a in the second limiting assembly 201 is disposed in the limiting groove U. It should be noted that FIG. 10 is schematically illustrated with the first limiting assembly 101 including two first limiting portions 101a and the second limiting assembly 201 including one second limiting portion 201a. In other implementations, the quantity of first limiting portions 101a in the first limiting assembly 101 is more than two, and the quantity of second limiting portions 201a in the second limiting assembly 201 is more than one, which is not limited in the embodiments of the present disclosure.

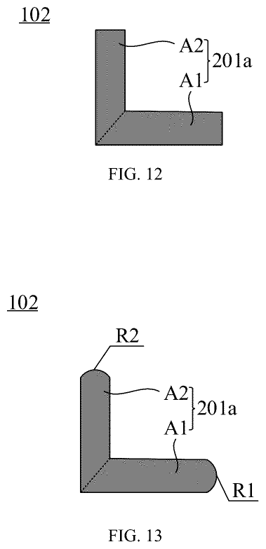

In some embodiments, referring to FIG. 11, FIG. 11 is a top view of a first limiting assembly according to some embodiments of the present disclosure. The limiting grooves U in the first limiting assembly 101 includes a first sub-groove U1 and a second sub-groove U2 communicated with the first sub-groove U1. The extension direction of the first sub-groove U1 intersects with the extension direction of the second sub-groove U2. Referring to FIG. 12, FIG. 12 is a top view of a second limiting assembly according to some embodiments of the present disclosure. The second limiting portion 201a in the second limiting assembly 201 includes a first sub-limiting plate A1 disposed in the first sub-groove U1, and a second sub-limiting plate A2 disposed in the second sub-groove U2.

In one possible implementation, the extension direction of the first sub-groove U1 in the limiting groove U is parallel to the first direction X, and the extension direction of the second sub-groove U2 in the limiting groove U is parallel to the second direction Y. Correspondingly, the extension direction of the first sub-groove U1 is perpendicular to the extension direction of the second sub-groove U2. In this way, in the process of bonding the display substrate 100 to the drive assembly 200, in the case that the first sub-limiting plate A1 in the second limiting portion 201a extends into the first sub-groove U1 in the limiting groove U, it can be ensured that the drive assembly 200 does not move in the second direction Y with respect to the display substrate 100 by the portion of the first sub-limiting A1 which extends into the first sub-groove U1. In the case that the second sub-limiting plate A2 in the second limiting portion 201a extends into the second sub-groove U2 in the limiting groove U, it can be ensured that the drive assembly 200 does not move in the first direction X with respect to the display substrate 100 by the portion of the second sub-limiting A2 that extends into the second sub-groove U2. In other possible implementations, the extension direction of the first sub-groove U1 is not perpendicular to the extension direction of the second sub-groove U2. For example, the angle between the extension direction of the first sub-groove U1 and the extension direction of the second sub-groove U2 ranges from 600 to 120°, which is not limited in the embodiments of the present disclosure.

In some embodiments, as shown in FIG. 12, in the second limiting portion 201a, one side of the first sub-limiting plate A1 is fixedly connected to one side of the second sub-limiting plate B1. In the present disclosure, because the first sub-limiting plate A1 needs to extend into the first sub-groove U1, the second sub-limiting plate A2 needs to extend into the second sub-groove U2. Therefore, the angle between the first sub-limiting plate A1 and the second sub-limiting plate A2 is equal to the angle between the extension direction of the first sub-groove U1 and the extension direction of the second sub-groove U2. In this way, the angle between the first sub-limiting plate A1 and the second sub-limiting plate A2 ranges from 60° to 120°.

In this way, in the case that the extension direction of the first sub-groove U1 is perpendicular to the extension direction of the second sub-groove U2, the angle between the first sub-limiting plate A1 and the second sub-limiting plate A2 in the second limiting portion 201a is 90°. That is, the second limiting portion 201a is a limiting plate of the L-shape. In the case that the extension direction of the first sub-groove U1 is not perpendicular to the extension direction of the second sub-groove U2. For example, in the case that the angle between the two is 60° or 120°, the angle between the first sub-limiting plate A1 and the second sub-limiting plate A2 in the second limiting portion 201a is 600 or 120°. That is, the second limiting portion 201a is a V-shaped limiting plate. It should be noted that the accompanying drawings in the embodiments of the present disclosure are all schematically illustrated with the second limiting portion 201a being an L-shaped limiting plate.

In the embodiments of the present disclosure, as shown in FIG. 13, FIG. 13 is a top view of another second limiting assembly according to some embodiments of the present disclosure. In the second limiting portion 201a, a first chamfer R1 is disposed at an edge of the side, away from the second sub-limiting plate A2, of the first sub-limiting plate A1, and/or a second chamfer R2 is disposed at an edge of the side, away from the first sub-limiting plate A1, of the second sub-limiting plate A2. It should be noted that FIG. 12 is schematically illustrated as an example of the second limiting portion 201a in which both the first chamfer R1 and the second chamfer R2 are provided.

The first chamfer R1 and the second chamfer R2 are rounded chamfers (also referred to as rounded corners). In this way, during the process of bonding the display substrate 100 to the drive assembly 200, in the case that the conductive adhesive 300 between the display substrate 100 and the drive assembly 200 is flowing, the adhesive in the flowing state is less likely to be blocked by the end portion of the second limiting portion 201a, such that the adhesive is able to flow outwardly normally.

In some embodiments, as shown in FIG. 11, in the first limiting assembly 101, the shape of at least one of the two first limiting portions 101a disposed on both sides of the second limiting portion 201a is the same as the shape of the second limiting portion 201a. Exemplarily, the first limiting portion 101a of the first limiting assembly 101 that has the same shape as the second limiting portion 201a includes a third sub-limiting plate B1 and a fourth sub-limiting plate B2.

One side of the third sub-limiting plate B1 is fixedly connected to one side of the fourth sub-limiting plate B2, and the angle between the third sub-limiting plate B1 and the fourth sub-limiting plate B2 is equal to the angle between the first sub-limiting plate A1 and the second sub-limiting plate A2. In this way, the angle between the third sub-limiting plate B1 and the fourth sub-limiting plate B2 also ranges from 600 to 120°.

In the present disclosure, there are various patterns of the side, away from the fourth sub-limiting plate B2, of the third sub-limiting plate B1 and the side, away from the third sub-limiting plate B1, of the fourth sub-limiting plate B2. The following three cases are illustrated as examples of the embodiments of the present disclosure.

In a first case, as shown in FIG. 11, the shapes of the two first limiting portions 101a in the first limiting assembly 101 are the same as the shape of the second limiting portion 201a disposed between the two. In each of the first limiting portions 101a, the shape of the side, away from the fourth sub-limiting plate B2, of the third sub-limiting plate B1 and the shape of the side, away from the third sub-limiting plate B1, of the fourth sub-limiting plate B2 are planar.

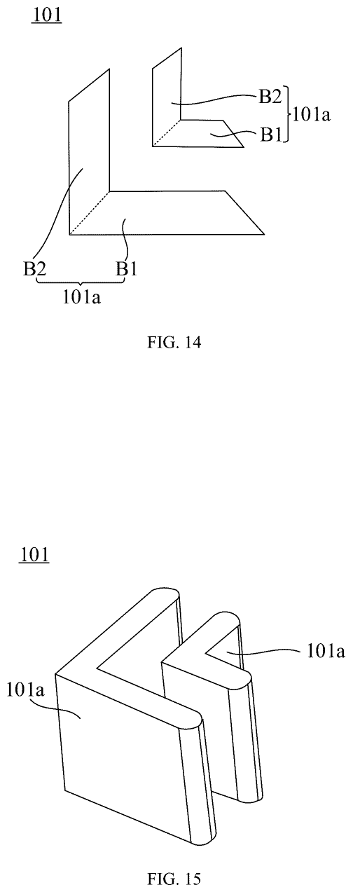

In a second case, as shown in FIG. 14, FIG. 14 is a top view of another first limiting assembly according to some embodiments of the present disclosure. The two first limiting portions 101a in the first limiting assembly 101 are the same as the shape of the second limiting portion 201a disposed between the two. In each of the first limiting portions 101a, the side, away from the fourth sub-limiting plate B2, of the third sub-limiting plate B1 is beveled, as is the side of the fourth sub-limiting plate B2 backing away from the third sub-limiting plate B1.

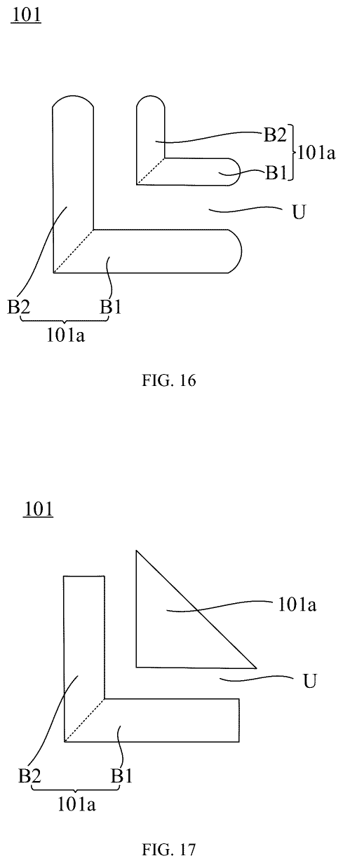

In a third case, as shown in FIGS. 15 and 16, FIG. 15 is a top view of still another first limiting assembly according to some embodiments of the present disclosure, and FIG. 16 is a three-dimensional view of the first limiting assembly illustrated in FIG. 15. The two first limiting portions 101a in the first limiting assembly 101 both have the same shape as the second limiting portion 201a disposed between the two, and in each of the first limiting portions 101a, a side, away from the fourth sub-limiting plate B2 side, of the third sub-limiting plate B1 and a side, away from the third sub-limiting plate B1, of the fourth sub-limiting plate B2 are both curved. That is, the rounded chamfers are formed at both the side, away from the fourth sub-limiting plate B2 side, of the third sub-limiting plate B1 and the side, away from the third sub-limiting plate B1, of the fourth sub-limiting plate B2. In this way, during the process of bonding the display substrate 100 to the drive assembly 200, in the case that the conductive adhesive 300 between the display substrate 100 and the drive assembly 200 is flowing, the adhesive in the flowing state is less likely to be blocked by the end portion of the first limiting portion 101a, which further improves the ability of the adhesive to flow between the display substrate 100 and the drive assembly 200.

In some embodiments, in the above three optional implementations, for the two first limiting portions 101a in the first limiting assembly 101, the size of the first limiting portion 101a close to the first bonding region 100a is smaller than the size of the first limiting portion 101a away from the first bonding region 100a. The following embodiments are to illustrate the dimensions of the two first limiting portions 101a in the first limiting assembly 101 as an example of the first case described above:

In the first limiting portion 101a away from the first bonding region 100a in the first limiting assembly 101, the length L1 of the third sub-limiting plate B1 and the length L2 of the fourth sub-limiting plate B2 are both less than or equal to the length of the first bonding electrodes 102 within the first bonding region 100a.

In addition, in the first limiting assembly 101, a width d1 of the first limiting portion 101a further away from the first bonding region 100a, a width d2 of the first limiting portion 101a closer to the first bonding region 100a, and a width d3 of the limiting groove U disposed between the two first limiting portions 101a, all need to be greater than or equal to 4 μm. The first bonding electrode 102 within the first bonding region 100a is formed by a patterning process, and in the process of the patterning process, the etching precision of the first bonding electrode 102 is usually 1 μm. In the process of bonding the drive assembly 200 to the display substrate 100, the alignment precision between the second bonding electrode 202 in the drive assembly 200 and the first bonding electrode 101 in the display substrate 100 is also typically 1 μm. For this reason, in the case that the above d1, d2 and d3 are all greater than or equal to 4 μm, it can be ensured that the first bonding assembly 101 can perform a better limitation with the second bonding assembly 102 during the process of bonding of the drive assembly 200 to the display substrate 100.

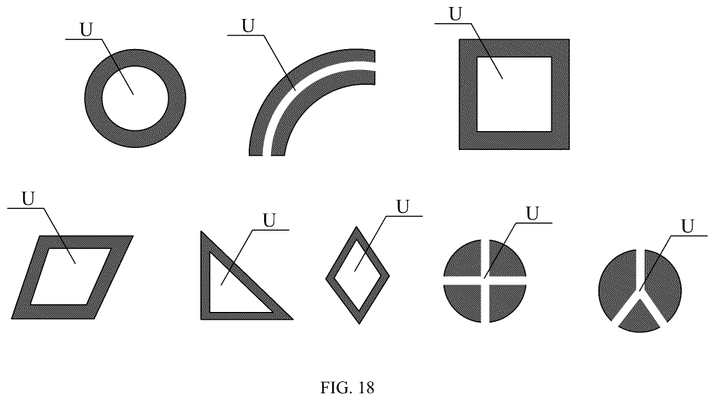

It is to be noted that all the above three cases are illustrated as an example of the two first limiting portions 101a in the first limiting assembly 101, both of which have the same shape as the second limiting portion 201a disposed between them. In other possible implementations, one of the first limiting portions 101a in the first limiting assembly 101 has the same shape as the second limiting portion 201a, while the other first limiting portion 101a has a shape that is different from the second limiting portion 201a. For example, as shown in FIG. 17, FIG. 17 is a top view of still another first limiting assembly according to some embodiments of the present disclosure. In the first limiting assembly 101, one first limiting assembly 101a includes a third sub-limiting plate B1 and a fourth sub-limiting plate B2, while the shape of the other first limiting portion 101a is trigonal, and this trigonal first limiting portion 101a is disposed closer to the first bonding region relative to the first limiting portion 101a including the third sub-limiting plate B1 and the fourth sub-limiting plate B2 100a.

It should also be noted that all of the above embodiments are illustrated schematically with the example of the limiting groove U in the first limiting assembly 101 including a first sub-groove U1 and a second sub-groove U2 having intersecting extension directions. In other possible implementations, the limiting groove U in the first limiting assembly 101 can have other shapes. For example, referring to FIG. 18, FIG. 18 is a possible top view of a first limiting assembly in a different scenario according to some embodiments of the present disclosure. The shape of the limiting groove U in the first limiting assembly 101 can be any one of: a circle, an arc, a square, a parallelogram, a triangle, a diamond, a cross, and a Y-shape. The shape of the second limiting portion 201a in the second limiting assembly 201 needs to match the shape of the limiting groove U. For example, in the case that the shape of the limiting groove U is circular, the second limiting portion 201a is in the form of a circular column. In this way, it can be ensured that the second limiting portion 201a, upon being extended into the limiting groove U, can be abutted against the first limiting portion 101a.

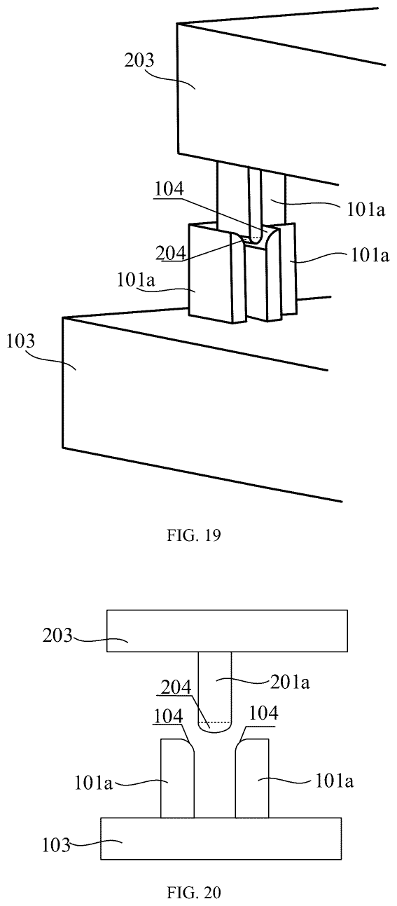

In some embodiments, reference is made to FIG. 19, FIG. 19 is a partially enlarged view of a display device according to some embodiments of the present disclosure. In the display substrate 100, a first guide structure 104 is disposed on a side, away from the first substrate 103, of the first limiting portion 101a, and/or, in the drive assembly 200, a second guide structure 204 is disposed on a side, away from the second substrate 203, of the second limiting portion 201a. It is to be noted that FIG. 19 is illustrated with the first limiting portion 101a with the first guide structure 104, and the second limiting portion 201a with a second guide structure 204 as an example for schematic illustration.

In this way, in the process of bonding the drive assembly 200 to the display substrate 100, the first guide structure 104 and/or the second guide structure 204 enable the second limiting portion 201a in the second limiting portion 201 to be easily inserted into the limiting groove U in the first limiting portion 101.

For example, referring to FIG. 20, FIG. 20 is a cross-section diagram of a first limiting assembly prior to being engaged with a second limiting assembly according to some embodiments of the present disclosure. In the first limiting assembly 101, the first guide structure 104 disposed on the side, away from the first substrate 103, of the first limiting portion 101a includes a third chamfer disposed on the side, close to the limiting groove U, of the first limiting portion 101a, and/or, in the second limiting assembly 201, the second guide structure 204 disposed on the side, away from the second substrate 203, of the second limiting portion 201a includes a fourth chamfer disposed on the side, close to the side of the first limiting portion 101a, of the second limiting portion 201a. It should be noted that FIG. 20 is schematically illustrated as an example with the first limiting portion 101a having the first guide structure 104, the first guide structure 104 including a third chamfer, the second limiting portion 201a having a second guide structure 204, and the second guide structure 204 including a fourth chamfer.

The third chamfer and the fourth chamfer are rounded chamfers (also referred to as rounded corners). In this way, in the process of bonding the display substrate 100 to the drive assembly 200, the cooperation of the third chamfer and the fourth chamfer can allow the second limiting portion 201a to be inserted into the limiting groove U in the first limiting assembly 101 more easily.

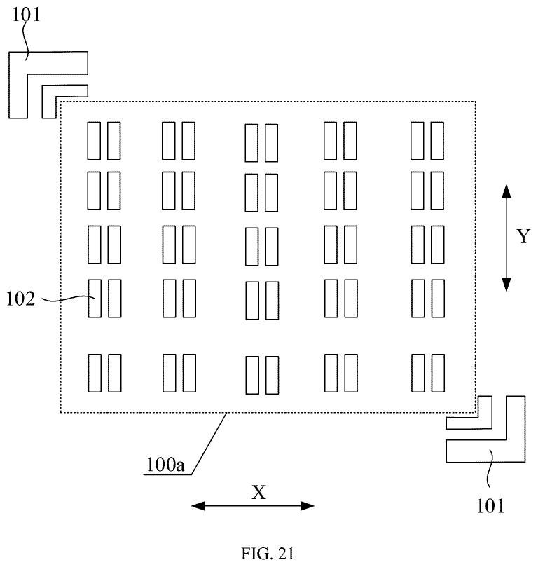

In some embodiments, as shown in FIG. 21, FIG. 21 is a partial top view of a display substrate at a first bonding region according to some embodiments of the present disclosure. The shape of the first bonding region 100a in the display substrate 100 is square, and a plurality of first limiting assemblies 101 in the display substrate 100 are disposed at least at diagonal positions of the first bonding region 100a. In this way, in the process of bonding the drive assembly 200 to the display substrate 1000, the movement of the drive assembly 200 in the first direction X and the movement of the drive assembly 200 in the second direction Y can be further limited by the cooperation between the first limiting assemblies 101 in the display substrate 100 and the second limiting assemblies 201 in the drive assembly 200.

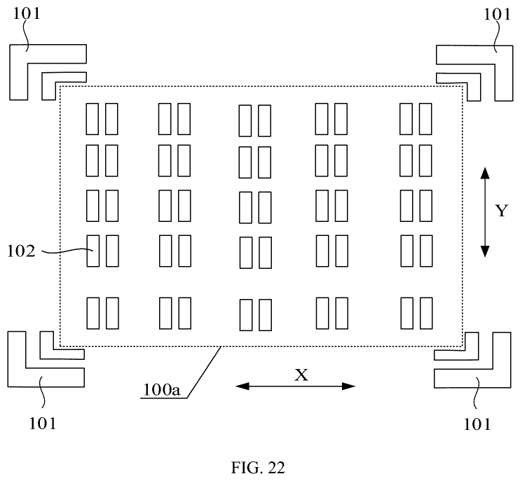

It should be noted that FIG. 21 is illustrated by showing an example of the substrate 100 including two first limiting assemblies 101, and these two limiting assemblies 101 are provided at a set of diagonal positions of the first bonding region 100a. In other possible implementations, as shown in FIG. 22, FIG. 22 is a partial top view of another display substrate at a first bonding region according to some embodiments of the present disclosure. The display substrate 100 includes four first limiting assemblies 101, and the four first limiting assemblies 101 are disposed towards four corners of the first bonding region 100a respectively.

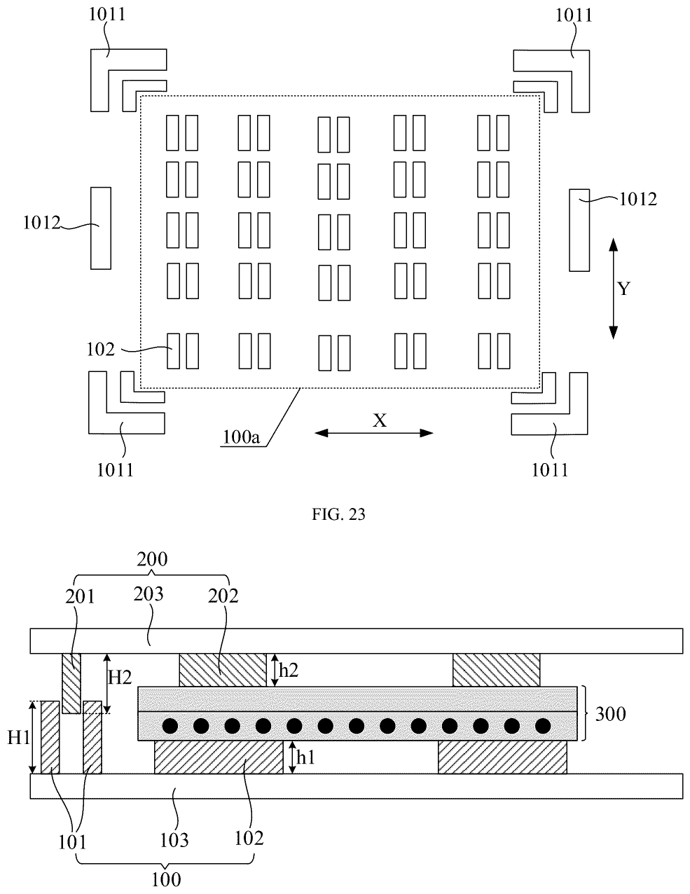

In some embodiments, referring to FIG. 23, FIG. 23 is a partial top view of still another display substrate at a first bonding region according to some embodiments of the present disclosure. The plurality of first limiting assemblies 101 in the display substrate 100 includes a first primary limiting assembly 1011 arranged toward the corners of the first bonding region 100a, and at least one first For example, in FIG. 23, the plurality of first limiting assemblies 101 includes four first primary limiting assemblies 1011 and two first auxiliary limiting assemblies 1012, and the four first primary limiting assemblies 1011 is disposed toward each of the four corners of the first bonding region 100a, and the two first auxiliary limiting assemblies 1012 primary opposite each other.

In this way, the plurality of second limiting assemblies 201 in the drive assembly 200 also need to include a plurality of second primary limiting assemblies and at least one second auxiliary limiting assembly. The second primary limiting assemblies are configured to be engaged with the first primary limiting assembly 1011 and the second auxiliary limiting assemblies are configured to be engaged with the first auxiliary limiting assembly 1012. In this way, during the bonding the drive assembly 200 to the display substrate 100, the movement of the drive assembly 200 in the first direction X can be further limited by the engagement between the first auxiliary limiting assembly 1012 and the second auxiliary limiting assembly.

The structure of the first primary limiting assembly 1011 is the same as the structure of the first limiting assembly 101 in the above embodiment, and the structure of the first auxiliary limiting assembly 1012 may or may not be the same as the structure of the first limiting assembly in the above embodiment. Similarly, the structure of the second primary limiting assembly is the same as the structure of the second limiting assembly 201 in the above embodiment, and the structure of the second auxiliary limit may or may not be the same as the structure of the second limiting assembly in the above embodiment, which is not limited in the embodiments of the present disclosure.

It is to be noted that FIG. 23 is illustrated as an example in the case that the structure of the first auxiliary limiting assembly 1012 is different from the structure of the first limiting assembly in the above embodiment. The first auxiliary limiting assembly 1012 includes a linearly shaped limiting plate. In this way, the second auxiliary limiting assembly in the drive assembly 200 further includes a linearly shaped limiting plate.

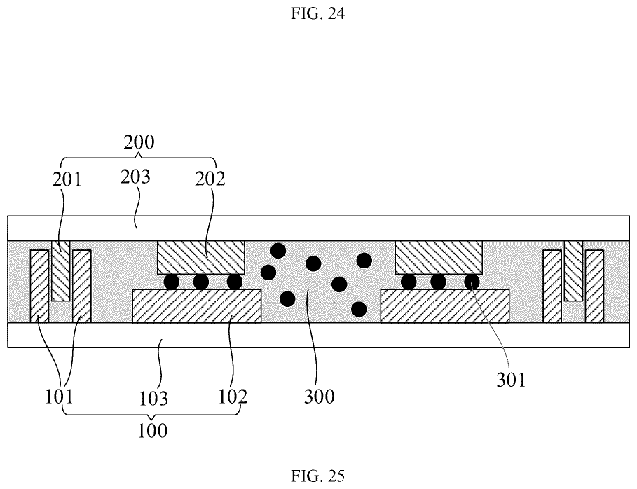

In some embodiments, as shown in FIG. 24, FIG. 24 is a cross-section diagram of a display substrate and a drive assembly prior to being bound in a display device according to some embodiments of the present disclosure. In the thickness direction of the display substrate 100, a height H1 of the first limiting assembly 101 in the display substrate 100 is greater than or equal to a height h1 of the first bonding electrode 102, and a height H2 of the second limiting assembly 201 in the drive assembly 200 is greater than or equal to a height h2 of the second bonding electrode 202. It is to be noted that FIG. 24 is shown as a cross-section of the display substrate 100 with the height H1 of the first limiting assembly 101 greater than the height h1 of the first bonding electrode 102, and the height H2 of the second limiting assembly 201 is greater than the height h2 of the second bonding electrode 202. In this way, it can be ensured that the second limiting portion 201a in the second limiting assembly 201 can smoothly extend into the limiting recess U in the first limiting assembly 101 during the process of bonding the display substrate 100 to the drive assembly 200.

In embodiments of the present disclosure, as shown in FIG. 24, the sum of the height H1 of the first limiting assembly 101 and the height H2 of the second limiting assembly 201 in the thickness direction of the display substrate 100 needs to be greater than the sum of the height h1 of the first bonding electrode 102, the height h2 of the second bonding electrode 202, and the thickness h3 of the conductive adhesive 300 prior to bonding. In this way, in the case that the conductive adhesive 300 prior to bonding bonds the display substrate 100 with the drive assembly 200, a small portion of the second limiting portion 201a in the second limiting assembly 201 is able to extend into the limiting groove U in the first limiting assembly 101. During the bonding process, after applying a pressing force to the drive assembly 200, the second limiting portion 201a is able to move downwardly within the limiting groove U, and the movement of the drive assembly 200 relative to the display substrate 100 in the horizontal direction is limited by the second limiting portion 201a being abutted against the first limiting portion 101a.

In the present disclosure, as shown in FIG. 25, FIG. 25 is a cross-section diagram of a display substrate and a drive assembly upon bonding in another display device according to some embodiments of the present disclosure. In the case that the display substrate 100 is bound to the drive assembly 200, the second bonding electrode 202 is electrically connected to the first bonding electrode 102 by the conductive particles 301 in the conductive adhesive 300. In the thickness direction of the display substrate 100, the height H2 of the second limiting assembly 201, is smaller than the height H1 of the first limiting assembly 101. In this way, because the display substrate 100 is a flexible display substrate, in the case that the height H2 of the second limiting assembly 201, is smaller than the height H1 of the first limiting assembly 101, upon bonding the display substrate 100 to the drive assembly 200, it can be ensured that the end portion of the second limiting assembly 201 away from the second substrate 203 does not come into contact with the display substrate 100, and thus it can be ensured that the second limiting assembly 201 does not scratch the display substrate 100.

In addition, the height H1 of the first limiting assembly 101 is less than or equal to the sum of the height h1 of the first bonding electrode 102, the height h2 of the second bonding electrode 202, and the particle size of the conductive particles 301 in the conductive adhesive 300. In this way, in the case that the display substrate 100 is bound and connected to the drive assembly 200, it can be ensured that the end, away from the first substrate 103, of the first limiting assembly 101 is at most in contact with the drive assembly 200, and the first limiting assembly 101 does not apply a force to the drive assembly 200, so as to ensure a high reliability of the display substrate 100 upon being bound to the drive assembly 200.

In some embodiments, the first limiting assembly 101 and the first bonding electrode 102 in the display substrate 100 are disposed in one layer and have the same material, and/or, the second limiting assembly 201 and the second bonding electrode 202 in the drive assembly 200 are disposed in one layer and have the same material as.

It is to be noted that, in the embodiments of the present disclosure, two structures being disposed in one layer and having the same material indicated that the two structures are formed by one composition process. The composition process includes photoresist coating, exposure, development, etching, and photoresist stripping. For example, the first limiting assembly 101 and the first bonding electrode 102 are being disposed in one layer and having the same material indicated that the first limiting assembly 101 and the first bonding electrode 102 are formed by one composition process.

In this way, in the case that the first limiting assembly 101 and the first bonding electrode 102 in the display substrate 100 are disposed in one layer and have the same material, the first limiting assembly 101 and the first bonding electrode 102 can be formed on the first substrate 103 simultaneously by one process, which can effectively simplify the manufacturing process of the display substrate 100. Similarly, in the case that the second limiting assembly 201 and the second bonding electrode 202 in the drive assembly 200 are disposed in one layer and have the same material, the second limiting assembly 201 and the second bonding electrode 202 are formed on the second substrate 203 simultaneously by one process, which can effectively simplify the manufacturing process of the drive assembly 200.

In the embodiments of the present disclosure, in the case that the first bonding electrode 102 and the first limiting assembly 101 are disposed in one layer and have the same material, and the first limiting assembly 101 is also conductive, in order to ensure that the first limiting assembly 101 does not interfere with the normal operation of other conductive structures in the display substrate 100, it is necessary to allow the first limiting assembly 101 to be insulated from the conductive structures in the display substrate 100. And/or, in the case that the second bonding electrode 202 and the second limiting assembly 201 are disposed in one layer and have the same material, and the second limiting assembly 201 is also conductive, in order to ensure that the second limiting assembly 201 does not interfere with the normal operation of other conductive structures in the drive assembly 200, it is necessary to allow the second limiting assembly 201 to be insulated from the conductive structures within the drive assembly 200.

In summary, the embodiment of the present disclosure provides a display device including a display substrate and a drive assembly. During the process of bonding the first bonding region in the display substrate to the second bonding region in the drive assembly by the conductive adhesive, the conductive adhesive is in a flowing state. By the engagement between the second limiting assembly in the drive assembly and the first limiting assembly in the display substrate, the relative movement between the drive assembly and the display substrate can be restricted, such that the adhesive in the flowing state does not drive the drive assembly to move relative to the display substrate. In this way, the probability of offset between the second bonding electrode in the drive assembly and the corresponding first bonding electrode in the display substrate can be effectively reduced, such that the drive assembly and the display substrate are bound with higher precision, the effect of the electrical connection between the second binding electrode and the corresponding first binding electrode can be effectively improved, and the display substrate achieves a better display effect.

Described above are only exemplary embodiments of the present disclosure and are not intended to limit the application, and any modifications, equivalent substitutions, improvements, and the like, within the spirit and principles of the present disclosure shall be included in the scope of protection of the present disclosure.

1. A display device, comprising: a display substrate and a drive assembly; wherein
the display substrate has a first bonding region, and the drive assembly has a second bonding region corresponding to the first bonding region; and
the display substrate includes a first limiting assembly disposed outside the first bonding region, and the drive assembly includes a second limiting assembly disposed outside the second bonding region and engaged with the first limiting assembly;
wherein the first limiting assembly is configured to engage with the second limiting assembly to restrict relative movement between the drive assembly and the display substrate during bonding the first bonding region to the second bonding region.

2. The display device according to claim 1, wherein the display substrate comprises a plurality of first limiting assemblies, and the drive assembly comprises a plurality of second limiting assemblies, the plurality of first limiting assemblies being in one-to-one correspondence to the plurality of second limiting assemblies;
wherein each of the first limiting assemblies comprises at least one first limiting portion, each of the second limiting assemblies comprises at least one second limiting portion, wherein the first limiting portion of the first limiting assembly is configured to be abutted against the second limiting portion of the second limiting assembly corresponding to the first limiting assembly.

3. The display device according to claim 2, wherein in a case that each of the first limiting assemblies comprises the first limiting portion and each of the second limiting assemblies comprises the second limiting portion, each of the first limiting assemblies is disposed on a side, closer to the first bonding region, relative to the second limiting assembly corresponding to the first limiting assembly, or each of the second limiting assemblies is disposed on a side, closer to the first bonding region, relative to the first limiting assembly corresponding to the second assembly.

4. The display device according to claim 2, wherein a limiting groove is disposed in one of the first limiting assembly and the second limiting assembly, and the other of the first limiting assembly and the second limiting assembly is disposed in the limiting groove.

5. The display device according to claim 4, wherein the first limiting assembly comprises at least two first limiting portions, two adjacent first limiting portions are configured to define the limiting groove, and the second limiting portion of the second limiting assembly is disposed in the limiting groove.

6. The display device according to claim 5, wherein the limiting groove comprises a first sub-groove and a second sub-groove in communication with the first sub-groove, wherein an extension direction of the first sub-groove is intersected with an extension direction of the second sub-groove, and the second limiting portion comprises a first sub-limiting plate disposed in the first sub-groove and a second sub-limiting plate disposed in the second sub-groove.

7. The display device according to claim 6, wherein one side of the first sub-limiting plate is fixedly connected to one side of the second sub-limiting plate.

8. The display device according to claim 7, wherein there is at least one of:
a first chamber being formed at an edge of a side, away from the side of the second sub-limiting plate, of the first sub-limiting plate, or
a second chamber is-being formed at an edge, away from the first sub-limiting plate, of the second sub-limiting plate.

9. The display device according to claim 7, wherein an angle between the first sub-limiting plate and the second sub-limiting plate ranges from 600 to 120°.

10. The display device according to claim 7, wherein a shape of at least one of the first sub-limiting portions disposed on both sides of the second sub-limiting portion has is same as a shape of the second sub-limiting portion.

11. The display device according to claim 4, wherein a shape of the limiting groove comprises any one of: a circle shape, an arc shape, a square shape, a parallelogram shape, a triangle shape, a rhombus shape, a cross shape, or a Y-shape.

12. The display device according to claim 1, wherein
the display substrate further comprises a first substrate, wherein the first limiting portion is fixed to the first substrate; and
the drive assembly further comprises a second substrate, wherein second limiting portion is fixed to the second substrate;
wherein there is at least one of: a first guide structure is-being disposed on a side, away from the first substrate, of the first substrate, or a second guide structure being disposed on a side, away from the second substrate, of the second substrate.

13. The display device according to claim 12, wherein there is at least one of:
the first guide structure comprising a third chamfer, wherein the third chamfer is disposed on a side, close to the limiting groove, of the first limiting portion; or
the second guide structure comprising a fourth chamfer, wherein the fourth chamfer is disposed on a side, close to the first limiting portion, of the second limiting portion.

14. The display device according to claim 2, wherein a shape of the first bonding region is a square shape, and the plurality of first limiting assemblies are disposed at least at diagonal positions of the first bonding region.

15. The display device according to claim 14, wherein the plurality of the first limiting assemblies comprise a first primary limiting assembly arranged towards corners of the first bonding region, and at least one first auxiliary limiting assembly arranged between two adjacent corners of the first bonding region.

16. The display device according to claim 14, wherein the display substrate further comprises a plurality of first bonding electrodes disposed in the first bonding region, and the drive assembly further comprises a plurality of second bonding electrodes disposed in the second bonding region;
wherein the plurality of first bonding electrodes are one-to-one electrically connected to the plurality of second bonding electrodes in response to the first bonding region being bounden to the second bonding region, in a thickness direction of the display substrate, a height of the first limiting assembly is greater than or equal to a height of the first bonding electrodes, and a height of the second limiting assembly is greater than or equal to a height of the second bonding electrodes.

17. The display device according to claim 16, wherein there is at least one of:
the first limiting assembly and the first bonding electrode being disposed in one layer have a same material, or, the second limiting assembly and the second bonding electrode being disposed in one layer and have a same material.

18. The display device according to claim 17, wherein the first bonding electrode is configured to be electrically connected to a conductive structure within the display substrate, and the second bonding electrode is configured to be electrically connected to a conductive structure within the drive assembly;
wherein there is at least one of: the conductive structure within the display substrate being insulated from the first limiting assembly, or the conductive structure within the drive assembly being insulated from the second limiting assembly.

19. The display device according to claim 16, wherein the display substrate further comprises a plurality of light-emitting elements, the first bonding electrode is electrically connected to the light-emitting elements, the drive assembly further comprises an integrated circuit, and the second bonding electrode is electrically connected to the integrated circuit.

20. The display device according to claim 16, wherein the display device further comprises a conductive adhesive disposed between the display substrate and the drive assembly, and the first bonding region is bound to the second bonding region via the conductive adhesive.
